(19) United States
(12) Patent Application Publication
(10) Pub. No.: US 2012/0155758 A1
(43) Pub. Date: Jun. 21, 2012

(54) ELECTRONIC COMPONENT WITH THREE ASSOCIATED FUNCTIONS

(76) Inventors: Claude Annie Perrichon, L'Isle d' Abeau (FR); Francois Giry, Challes les Eaux (FR); Jose Buendia, Bourgon-Jallieu (FR); Pierre Piccaluga, Macon (FR)

(21) Appl. No.: 12/672,477

(22) PCT Filed: Mar. 3, 2008
(86) PCT No.: PCT/FR08/00273

§ 371 Date: Jan. 17, 2011

(51) Int. Cl. G06T 5/00; F03G 7/08; H03G 3/20

(52) U.S. Cl. 382/167; 381/61; 310/339

(57) ABSTRACT

Electronic component which modifies, by electronic re-equilibration, mechanical efficiencies, audio-visual effects, and food products. The electronic component eCRT is a regulator which, like entropy, regulates the exchanges of natural equilibrium of the information of electro-magnetic charges with electronic charges. This equilibrium is to naturally clean the air and the excess of magnetic charges around apparatus or in inert products that have accumulated non-useful electrons which are then absorbed, attracted captured by the trap of the metallic components. Nanotechnology makes it possible to see the migration of the magnetic fields converted into electric current whose piezo is fed in order to vibrate. These functions are all natural but, associated together, they create novel functions specific to this method. This vision of nano-technology makes it possible to solve, on a large scale, invisible solutions, through a vision of suitable scale. The application to sound in ambient space of the eCRT electronic component is the supreme demonstration of the audio magnetic loss captured by the piezo-electricity eCRT which captures the magnetic field instantaneously and transforms the magnetic information into electric current, according to the audio modulation. This audio electrical modulation by the thirst, the transience of the piezoelectricity is transformed into audible mechanical motion of the sound lost initially by the coil.

This international patent application filing is the synthesis of the work carried out over the last three years, which has been the subject of patent application filings No. 1 “Management of active electrons” No: PCT/FR2006/001253 and No. 2 “Reducing the boundary layer of aerodynamic effects” No: PCT/FR2007/001353 for which we claim precedence priority for this filing, to claim the generality of the functions of the electronic component called eCRT based on the three simultaneous activities interlinked in this electronic component.

The two texts of patents 1 and 2 refer to the method of the electronic component which involves absorbing magnetic charges through the metallic material included in the piezoelectric component which transforms them and eliminates them in the form of mechanical vibrations.

No. 1: absorbs the radiant or electromagnetic currents flowing at the periphery of the electrical conductors, or on the electrical circuits, augmented by a mini-inductor which accelerates the self-induction of the magnetic fields. Since the conductor is embedded in its magnetic pollution through immersion in the associated piezoelectric, the information or power current becomes clean again in the operating electrical circuit.

No. 2 is an identical but external function which cleans the magnetic charge which is absorbed by the metallic filler. The introduction of copper, gold, iron or metal powder into the piezo makes it possible to convert the magnetic charge into electrical charge which is immediately transformed into mechanical motion. The metal can be in the form of small coils of a few turns to pick up the radiant magnetic field and transform it into electric current. Through experience, we have worked with metal or aluminum powder and, depending on the concentration, we record the more or less intense piezoelectric activity through the electric charge acquired in the powders or loops. A mini coil with the powder makes it possible to optimize the effects. However, a coil demands a specific frequency and amplitude. Powder with a certain density, concentration in the mixture of the piezo paste, makes it possible to receive a lot more current in frequencies and in amplitudes, without being specifically tuned. Powder makes it possible to obtain an overall holistic effect sensitive to all the magnetic charges working around the electronic component, less specific, but generally more sensitive depending on the fields of application.

The two technologies refer to the energies of weak links and to the Van der Waals dipoles, and the Laplace, Hertz, Lorentz, Gauss, Maxwell and Faraday laws.

The applications show a product with multiple applications that are managed by the eCRT component, a nonexhaustive list of the general applications of which is given below.
The first application case is a particular case which is the application to sound. The magnetic loss of loudspeakers is a loss of acoustic efficiency in the coils that we recover for the sound activity through the lost mechanical vibration of the membranes, vibration that is retrieved by the present method.
The second general application case in electricity is to eradicate the electromagnetic drawbacks that are superimposed such as CEMF, or the creation of electrical or electromagnetic disturbances.
The third application case is to remove the magnetic charges in fluids or gases to facilitate chemical exchanges. The magnetic charges are built up by the materials that are subject to friction or pressure variations, creating a trend away from the ideal stoichiometry, which prevents correct chemical reactions and which introduces exchange imbalances giving more NOX acidity residues in carburetion or more particles. The measurements carried out show, with the eCRT component, reductions by at least 15% of CO2 and reductions by 20% and more of NOX.

This case also covers the more or less strong adhesion between fluid components such as air and solids such as an airplane, or the hull of a boat and the friction on water, the attraction of which is reduced or increased so reducing at the same time the slowing down effect or friction freedom. This application relates directly to the laminar flows over airplane wings, or the friction tensions on the hulls of boats where the eCRT electronic component activates or discharges the electrical or electromagnetic charges caused by the speed of travel of the airplane or of the boat by application to the air or water travel medium.
The fourth application case is the absorption of the magnetic charges due to the friction of oils of liquids such as water in the casings or moving parts, such as gearwheels or similar that behave like Barlow wheels creating induced currents. The eCRT electronic component reduces the wear of the oils used. Applications in the machining field are significant.

The violent chemical exchanges from carburetion explosions create magnetic charges that have to be removed.
The fifth application case of the very nature of the material is due to the deformations of the materials that modify the fine electronic organization within the material. This reacts like a generalized but weak piezoelectric through circulations of electrons and transient currents, evinced by the ground braids on exhaust mufflers and suspensions. The different reactivities of the gearboxes testify to this through less noise and go faster through the gear changes. The applications are implemented by eCRT electronic components glued in position on the casings of the engines, powered axles, gear boxes. When mounted on skis with the eCRT linked from front to back by an electrical wire, the eCRT electronic component changes the dynamic behavior of the elasticity of the ski. In practice, the tension differentials of elastic mechanical stresses of the materials generate electron flows that are reorganized, corrected with the eCRT electronic component.

All these nonlimiting drawbacks of exemplary applications are known, listed in the various sectors, but the remedies and management of its flows are resolved and managed by the technology of the eCRT electronic component of the present invention which moves away from the linear binary vision towards a holographic ternary vision. The stated practical examples show the effectiveness of the eCRT electronic component in light of current knowledge and of the measurements made. The mechanical or electrical efficiencies have losses of effectiveness for which one of the responsible driving factors is the interacting force of the magnetic charges and of the build-ups of electrons in the inert masses that we take into account, improving the efficiencies and convenience of the machines and reducing magnetic and atmospheric pollutions.

The eCRT electronic component is a regulator which, like entropy, regulates the exchanges of natural balance of the information of electromagnetic charges with electronic charges. This balance is to naturally clean the air and the excess magnetic charges around devices or in inert products that have built up unwanted electrons which are then absorbed, attracted, picked up by the trap of the metallic components. Nanotechnology makes it possible to see the migration of the magnetic fields converted into electrical current with which the piezo is fed to vibrate. These functions are all natural but, when combined together, they create novel functions specific to this method. This vision of nanotechnology makes it possible to solve, on a large scale, invisible solutions, through a vision of suitable scale.

The application to sound in ambient space of the eCRT electronic component is the supreme demonstration of the audio-magnetic loss picked up by the piezoelectricity which, with metallic powder added to it, picks up the magnetic field instantaneously and transforms the magnetic information into electrical current, according to the audio modulation. This audio electrical modulation by the thirst, the transience of the piezoelectricity, is transformed into audible mechanical movement of the sound lost initially by the coil.

The lost harmonics are restored. This eCRT component device, when placed in front of an electro-acoustic loudspeaker, gives back the perception of sounds lost by the magnetic losses, affecting sound efficiency. The harmonics are returned in real time because the piezoelectric has no mechanical inertia and retransmits the information in real time. The overall sound is raised by 6 to 7 dB in acoustic power with a richness, an harmonic swell, without precedent in direct natural listening. The eCRT component also reduces the crosstalk that derives directly from electromagnetic self-inductions.

It is worth remembering the Teppaz from the 1960s which revolutionized the distribution of sound with its diamonds, its piezoelectric cells, picking up the ripples from vinyl disks. This first piezo application was the mechanical transposition of vibration into electrical current. Our case represents the reverse usage which, without requiring any physical or mechanical excitation, obtains a current through the electromagnetic charge which is picked up remotely by the metallic powder or the metallic loops on the parts where the magnetic flows circulate. The current picked up in this way will activate the vibrations of the piezo. The devices or “eCRT electronic component” will have a mass and a quantity that will be determined according to the spatiality and acoustics desired by those skilled in the art.

These three functions and these three actions:
1—magnetic field picked up by a metallic loop and/or metallic powder
2—magnetic field transformed into electric current
3—electric current transformed by the piezoelectric into mechanical vibration.
   These three phases characterize the eCRT electronic component: its functions are instantaneous, simultaneous and natural.

This electronic component is a new generation in the possible processing of the three transformations into different dimensions of information of 1 electronic type, 2 electromagnetic type and 3 mechanical type.

Its applications relate to all fields through its construction, its functions in mechanics and electronics in the dynamic phase and foodstuffs, these examples being nonlimiting.

These functions stem from the use of the servocontrolling of mechanical vibratory and electronic ripple performance and concern the use of electricity, the use of mechanics, solids, fluids and gases. Equally concerned are the active participants like the mechanics and the objects transported or transformed, since they are passive electron charge reservoirs. Any industrial engineering is affected by the circulation of the electrons agitated by mechanical or electrical actions or in stagnant waiting phases. All manufactured products are affected by the excess magnetic pollution such as fabrics give off high electrical voltages like other industries. Food products are affected, which is demonstrated by changes of taste, acidity in particular being affected.

A demonstration according to Faraday's law shows the authenticity of the eCRT technology: with an aluminum beer or Coca Cola can, the eCRT changes nothing. On the other hand, in glass, beer, wine or Coca Cola is truly optimized by removing the excess magnetic charges which cause the taste, the color of the product and sometimes its fluidity to be modified.

The technology is called eCRT because the three functions allow for instantaneous servocontrolling of the information by the electronic component. It is a component that acts in real time according to a number of functions that act and work in a holistic and instantaneous way, in other words are executed in real time “T0”, which is a fundamental innovation. This technology complements the microprocessor techniques which act only according to an electrical function variable, a technique in which Moore's law, by addition of its functions, remains in a binary plane and cannot access instantaneously, and remains in the past “T−1”.

The technology, the method of the eCRT component opens up instantaneous applications to the world of industry, computers and the world of the consumer in the audio-visual field. In the imaging field, the absence of CEMF, through the placement of the eCRT on the power supply wire of the charger and then on the power supply of the computer and the printer, means that the electrons are always available with no electromagnetic clouds. These eCRT arrangements greatly reduce distortion and give hitherto unachieved brightness and definition qualities. The number of pixels is immaterial; for example, a photograph of 5 million pixels with the eCRT component is better than a photograph of 10 million pixels without the eCRT component. The pixels are positioned by other information more exactly reflecting the reality photographed.

The area involving the use of alternating current is directly affected to reduce electromagnetic nuisances.

CEMF, or counter-electromotive force, creates a current in phase opposition which pollutes, disturbs the initial electrical information in electricity terms but also in mechanical terms. In practice, in mechanical terms, according to the Barlow wheel model, it is shown that a movement of mechanical parts generates a self-induced current in the reverse direction of rotation of the imposed movement. It is demonstrated that the piezoelectric that reacts under excitation by emitting electrical current or electrons through pressure on or deformation of the material is not an isolated case, but extends generally to all mechanics with smaller electron emissions, but with regard to large masses such as a car chassis or even springs subject to mechanical deformation, this becomes significant and has to be taken into consideration. Manufacturers have relegated to the masses an energy that is constantly renewed and that has become, for technology, essential to the management of global energies that have a considerable effect on efficiencies. Grounding arrangements testify to the circulation of electrical currents that have to be eliminated whether on industrial machinery in the textile industry, machining machines or automobiles, boats, airplanes. These currents circulate on electricity-conducting parts but stagnate and are built up on non-conducting components which are electron reservoirs. This is how, on a small scale, transistors and semiconductors were created.

On a large scale, the same applies, and such is the object of the management of the conversion of these energies by the eCRT component whose applications are given by the various international patent applications 1 and 2.

Since field, path and current are fundamentally linked in electricity, the resultant magnetic fields will without fail interact on electrical circuits, which self-induces the complex phases on computers, as on all electrical machinery. Optical fibers show the absence of these drawbacks and perfectly transmit the information without disturbance through the consistency of the signal, which is not the case with electrical current because of this CEMF disturbance through the phase modulation. The transportation of current by ABB as direct current shows that the magnetic radiations are very weak in the stable direction. Alternating current or current that varies in direction and amplitude brings with it all the trails of airborne or underwater or underground magnetic pollutions, which has given EDF a lot of problems.

It is therefore the dynamic variation of direction of the electrons which causes magnetic pollution. By removing these magnetic fields through the piezoelectric conversion, the circuits are cleaned of this pollution which is inherent in the use of the electronic effects of variation of the electrical current.

The eCRT component products are sophisticated piezo components based on various quartz silicas of different kinds with the insertion of copper or gold powder or powder formed of metals adapted in density according to the applications. Magnetic loops can, through coils of a few turns, be tuned to useful specific frequencies that are also immersed in the piezoelectric paste.

The mass of the product or products depends on the magnetic charges to be absorbed or the sound effects to be obtained. Those skilled in the art have available masses of 40 to 100 grams for acoustics to be affixed in front of the loudspeaker or speakers, in front of the grille close to the coil, in order to recover the magnetic leaks and be in the ambient medium to diffuse the sound radiation.

In the field of automobiles, buses, trucks or mechanics, the eCRT component masses are glued to the casings. The masses are 50, 100 to more than 200 grams.

For carburetion, the eCRT represents the optimization of stoichiometry, and the eCRT component pads are placed in front of the air filter intake.

In the field of electricity, the electronic component pads are affixed directly to the cables regulating the radiant fields.

In foodstuffs, the components are placed on glass wine or fruit juice bottles to eliminate the excess electrons of the magnetic charges built up by transport. In this context, wine-producers had observed the damaging effects without being able to remedy them but it is now a done deed. In an application to cut flowers, based on placing one or more eCRT electronic components in the water, the life of the flowers is greatly extended, with water that remains clean and clear for longer, a week at least.

With regard to airplanes or boats or brakes, the electrical dipoles to be corrected are regulated by eCRT components provided with a coil embedded in the piezo to channel the flows of electrons to be eliminated. One or more simple coils with few turns, of the order of several units, 10 to give a nonlimiting example that can be produced by those skilled in the art, are linked by an electrical wire to the ends of the wings from right to left of an airplane or the bow and stern of a boat, at the point where the voltages are created between the flows of electrons that are to be picked up and eliminated, where the surface polarity must be stabilized. This problem is known in aeronautics through the antenna devices placed behind the wings to eliminate the electromagnetic voltages created constantly on airplanes in flight. On brakes that are provided with the eCRT electronic component, stopping distances are observed to be reduced by 20% to more than 50% on cars, and on buses or trucks. On airplanes, rates of climb are immediately improved by at least 10 to 15% with a reduction in consumption of at least 15% with a significant reduction in vibrations, which is vital to the durability and to the safety of the equipment and passengers.

Explanation concerning electron flows within material:

Out-of-balance conditions generate tension forces on wheels. For example, adding a compensation mass means increasing the out-of-balance condition and therefore the electronic compensation load increases and fights against this deformation. Material loves its initial rest condition. This base memory is its reference point, a certain intelligence that opposes the imposed movements.

Electron-based matter is subject to Laplace's law which establishes the counter-electromotive force within the material, which is what generates the electron flows that oppose the deformations.

Thus, on our vehicles, we have removed the compensation masses and placed two 40 gram eCRT components symmetrically on the wheel, and there is no more vibration. For use on dynamic car wheels, two symmetrically implanted devices placed on the rim make it possible to compensate the out-of-balance conditions, balancing the wheels.

1. A method whereby an electronic component has three interlinked functions making it possible to pick up in real time the magnetic fields, or the electrons, that circulate or are built up in the mechanical parts or on the electrical circuits or wires, which are transformed by a piezoelectricity function in mechanical vibratory mode in order to eliminate the electron and electromagnetic pollutions.

2. The method as claimed in claim 1, characterized in that the modulation of the audio-magnetic field picked up is eliminated and translated into audio-mechanical movement by the eCRT electronic component to restore the harmonics lost from the loudspeakers in the form of magnetic field audio information lost by the coils, which is the example of all the active phases of the method without loss of information.

3. The method as claimed in claim 1, characterized by the three interlinked functions which are to pick up the magnetic fields which, according to the “field-path-current” Laplace law, become a current in a coil or metallic powder embedded in a piezoelectric paste which transforms them into mechanical vibrations, which is the piezoelectric function, thus eliminating the electromagnetic pollution of the excess electrons, stagnating in the inert material or in the moving parts, thus increasing the efficiencies and technical, mechanical and electrical performance levels of the machines and of management computers, PCs, and in the audio-visual world in particular, and in the food industry and industry in general.

4. An eCRT electronic device or component, characterized in that three functions are naturally interlinked through 1—the picking up of the magnetic fields obtained by metallic powders, such as copper, or aluminum, to give nonlimiting examples, depending on the density of these powders and/or one or more electrical mini-coils forming magnetic loops making it possible to pick up the translated magnetic fields, 2—electrons forming an electrical information current, powder or loops that are immersed in a complex piezoelectric paste formed by silicas, various quartzes which 3—translate the electrical charges into mechanical movements, eliminating the magnetic fields resulting from the various electrical, mechanical or chemical dynamic actions, thus eliminating the atmospheric electromagnetic and chemical pollutions resulting from carburetion action, cited as a nonlimiting example, and increasing the efficiencies of the machines in general.

5. The eCRT electronic device or component as claimed in claim 4, characterized by its use in the acoustic field by placing at least one eCRT electronic mass, for example of 50 grams, in front of the loudspeaker, which enhances the acoustics of its harmonics lost by the magnetic audio information losses of the coil, this application highlights all the technology of the eCRT electronic component increasing the acoustic efficiency by more than 3 dB and above all giving richness of sound through a harmonic swell that was lost.

6. The eCRT electronic device or component as claimed in claim 4, characterized by its use in the mechanical field which, placed in one or more 50, 100 or 200 gram masses glued onto the casings of the engines, gearbox or powered axles, to name a few nonlimiting exemplary embodiments, makes it possible to eliminate the magnetic charges to increase the mechanical efficiency and reduce oil wear.

7. The eCRT electronic device or component as claimed in claim 4, characterized by its use in the electricity field, regulating the counter-electromotive forces responsible for the alternating actions of complex currents, electromagnetic and electrical pollutions such as crosstalk are eliminated by placing a 50 to 100 gram mass of the eCRT electronic component on the power supply of the devices, giving performance levels for the world of electronic computer management and in the audio-visual field for images with greater sharpness and contrast, which repositions the pixels.

8. The eCRT electronic device or component as claimed in claim 4, characterized by its use for food products, taste enhancing conditions, in order to eliminate the stagnant electrons that modify its taste, the acidity in particular, by placing the eCRT electronic component masses close to or against a glass wine or fruit juice bottle, to give a nonlimiting example.

9. The eCRT electronic device or component as claimed in claim 4, characterized by its use for cut flowers which stay alive longer.

10. The eCRT electronic device or component as claimed in claim 4, characterized by its use in the field of fluids, gases, friction and dipoles, in which an electrical wire links, for example, the bow and the stern of a boat or the right and left wings of an airplane, to pick up their electron flows, or to stabilize their surface polarity.

11. The eCRT electronic device or component as claimed in claim 4, characterized by its use on the wheels of an automobile through two symmetrically implanted devices placed on the rim, to compensate for out-of-balance conditions, for wheel balancing.
